(19) United States
(12) Patent Application Publication
(10) Pub. No.: US 2025/0179643 A1
(43) Pub. Date: Jun. 5, 2025

(54) Apparatus and Method for Plasma Enhanced Chemical Vapour Deposition

(71) Applicant: LeydenJar Technologies B.V., Leiden (NL)

(72) Inventors: Pavel Kudlacek, Leiden (NL); Arjen Peter Didden, Leiden (NL)

(73) Assignee: LeydenJar Technologies B.V., Leiden (NL)

(21) Appl. No.: 18/845,852

(22) PCT Filed: Mar. 10, 2023
(86) PCT No.: PCT/NL2023/050118

§ 371 Date: Sep. 10, 2024

(30) Foreign Application Priority Data
Mar. 11, 2022 (NL) 2031257

(51) Int. Cl. C23C 16/511; C23C 16/24; C23C 16/44

(52) U.S. Cl. CPC C23C 16/511; C23C 16/24; C23C 16/4412

(57) ABSTRACT

The present invention relates to a linear plasma source assembly for plasma enhanced chemical vapour deposition comprising: a) a linear plasma source with first end and a second end comprising an antenna and an co-axial shielding element; and b) at least two gas manifolds, each comprising: at least one first gas conduit(s) provided with at least one first gas outlet ports for providing one or more first gaseous substances to a chemical vapour deposition chamber; and at least one exhaust gas conduit(s) each provided with at least two exhaust gas inlet port(s) for removing one or more exhaust gaseous substances from a chemical vapour deposition chamber.

This invention relates to a linear plasma source assembly suitable for plasma enhanced chemical vapour deposition (PECVD), an apparatus suitable for PECVD of a coating onto a substrate and a method for coating a substrate.

### BACKGROUND

Plasma enhanced chemical vapour deposition (PECVD) is widely employed in high volume coating of substrates with thin layers of deposited material. PECVD is used to deposit thing films from a gaseous vapour state onto substrates where it forms a solid state. The deposition process involves chemical reactions which occur after introductions of the feedstock gasses to the plasma. The plasma is typically generated by radio frequency (RF) or direct current (DC) discharge between two electrodes, with the space between the electrodes comprising the reacting gasses.

The deposition of thin-film coatings is used in various applications, such as electronics (battery materials, chips, etc), corrosion-resistant and tribological coatings, such as refractory films, for instance titanium or aluminium nitrides, carbides and oxides, coatings having optical, for instance anti-reflection, Solar-protection, filter, and other properties, coatings providing other biological or physiochemical properties, for instance antimicrobial, self-cleaning, hydrophilic, hydrophobic, oxygen impermeable packaging layers, and conductive films for various applications, such as for instance photovoltaics, LEDs, OLEDs, and organic photovoltaics.

The substrates in question may be of various types, such as glass, steel, copper films, ceramics, organic polymers, and thermoplastics.

For most industrial applications deposition of a film of homogeneous depth onto a substrate is desirable, especially for continuous processes. One approach employed in the art is the use of linear plasma sources for PECVD. These linear plasma sources typically comprise a rod-shaped antenna, which is arranged in a dielectric tube. This combination of rod-shaped antenna and dielectric tube is often referred to as the inner conductor of a coaxial conductor assembly. The outer conductor of is then formed by the plasma generated on the dielectric tube. This coaxial conductor arrangement forms the actual plasma source, and is often surrounded by a wall with an opening, through which the plasma emerges in the direction of a substrate to be coated. The plasma source extends along an axis that extends along the axis of the rod-shaped antenna with a defined length, with the opening in the wall typically having a width shorter than the length of the plasma source, thereby providing a linear plasma source. Examples of such sources can be found in DE 19812558 B4. An example of the method that employs a linear plasma source to deposit a homogeneous layer onto a roll of substrate is provided by U.S. Pat. No. 5,114,770 A.

The dielectric tubes must be able to withstand extended periods at the high temperatures that plasma generation entails. Materials typically used possess a melting point above 1000° C., such as quartz, which has a melting point of 1650 (±75)° C.

During PECVD processes using linear plasma sources, a first gas, which contains little to no chemically active deposition material of the process, is often introduced into the plasma source near the antenna, while a second gas, which contains most or all of chemically active deposition material of the process, is introduced into the plasma source near a substrate surface of the to be treated substrate.

PECVD processes utilising PECVD apparatuses with linear plasma sources may be advantageously used to provide substrates coated with a uniform coating of deposed material. However, serious issues remain in providing linear plasma source assemblies capable of simultaneously depositing materials on both sides of a linear plasma source simultaneously. The most pressing issue is ensuring homogeneous layer deposition onto both substates on either side of the linear plasma source.

### BRIEF SUMMARY OF THE DISCLOSURE

In accordance with the present inventions there is provided linear plasma source assemblies suitable for plasma enhanced chemical vapour deposition.

### BRIEF DESCRIPTION OF THE DRAWINGS

Embodiments of the invention are further described hereinafter with reference to the accompanying drawings, in which:

FIG. 1 is a cross-sectional view of a linear plasma source assembly according to an embodiment of a first aspect of the invention. The cross section is orthogonal to the principle rotational axis of the linear plasma source.

FIG. 2 is a cross-sectional view of the same linear plasma source assembly according to the embodiment of the first aspect of the invention, depicting the flow of gasses around the linear plasma source. The cross section is orthogonal to the principle rotational axis of the linear plasma source.

FIG. 3 is a cross-sectional view of the same linear plasma source assembly according to the embodiment of the first aspect of the invention, depicting the assembly in use for depositing material onto two moving substrates. The cross section is orthogonal to the principle rotational axis of the linear plasma source.

FIG. 4 is a cross-sectional view of a linear plasma source assembly according to an embodiment of the first aspect of the invention, which additionally comprises a plurality of plasma confinement magnets (6). The cross section is orthogonal to the principle rotational axis of the linear plasma source.

FIG. 5 is a cross-sectional view of a linear plasma source assembly according to an embodiment of a first aspect of the invention, comprising plasma constraining magnets (6). It depicts the flow of gasses around the linear plasma source and the magnet constrained plasma (G). The cross section is orthogonal to the principle rotational axis of the linear plasma source.

FIG. 6 is a cross-sectional view of the same linear plasma source assembly according to the embodiment of the first aspect of the invention as depicted in FIGS. 1-3. The cross section is parallel to, and cuts through, the principle rotational axis of the linear plasma source.

FIG. 7 is a cross-sectional view of the same linear plasma source assembly according to the embodiment of the first aspect of the invention as depicted in FIGS. 1-3 and 6. The cross section is parallel to, and cuts through, the principle rotational axis of the linear plasma source. The flow of the first gas is depicted.

FIG. 8 is a top-down (birds-eye) view of the linear plasma source assembly according to the embodiment of the first aspect of the invention as depicted in FIGS. 1-3, 6 and 7.

FIG. 9 is a top-down (birds-eye) view of the same linear plasma source assembly according to the embodiment of the first aspect of the invention as depicted in FIGS. 1-3 and 6-8. The arrows depict the flow of the second gas or gasses and the exhaust gas or gasses.

FIG. 10 is a cross-sectional view of a linear plasma source assembly according to an embodiment of a first aspect of the invention, comprising plasma constraining magnets (6). The cross section is orthogonal to the principle rotational axis of the linear plasma source.

FIG. 11 is a cross-sectional view of a linear plasma source assembly according to an embodiment of the first aspect of the invention, comprising a waveguide (11). The cross section is parallel to, and cuts through, the principle rotational axis of the linear plasma source.

FIG. 12 is a top-down (birds-eye) view of a linear plasma source assembly according to an embodiment of the first aspect of the invention, comprising a waveguide (11).

FIG. 13 is a cross-sectional view of a linear plasma source assembly according to an embodiment of the first aspect of the invention, in which the linear plasma source assembly comprises two radio wave source per linear plasma source (7a).

FIG. 14 is a cross-sectional view of the same linear plasma source assembly as depicted in FIGS. 1-3 and 6-9, used in a method according to the third aspect of the invention.

### DETAILED DESCRIPTION

In a first aspect, the present invention concerns a linear plasma source assembly (1) for plasma enhanced chemical vapour deposition comprising: a) a linear plasma source (2) with first end (2a) and a second end (2b) comprising an antenna (7) and an co-axial shielding element (8); and b) at least two gas manifolds (9), each comprising i) at least one first gas conduit(s) (3) provided with at least one first gas outlet ports (3a) for providing one or more first gaseous substances to a chemical vapour deposition chamber; ii) at least one exhaust gas conduit(s) (5) each provided with at least two exhaust gas inlet port(s) (5a) for removing one or more exhaust gaseous substances from a chemical vapour deposition chamber.

The linear plasma source advantageously comprises an antenna and a co-axial shielding element. Suitable internal-type linear inductively coupled plasma sources feature a linear metal antenna section within a coaxial dielectric tube section. The antenna sections may be provided as a single metal rod, or may be provided as more complicated serpentine types, comb/double-comb types, U-shaped types. By way of non-limiting example, suitable metals from which the antenna may be made may be selected from copper, aluminium, silver, alloys thereof or any other metal or metal alloy with sufficient electrical conductivity. Alternative geometries can be considered. Suitable linear microware plasma sources are described in DE 19812558 A1, DE 19503205 C1, WO 2012062754 A1 and DE 102010027619 B3. The linear microwave plasma sources preferably comprise: a linear antenna, an insulating tube fitted co-axially around the linear antenna.

Alternatively, the linear microwave plasma sources preferably comprise: a plurality of closely bundled linear antennas and an insulating tube fitted around the linear antennas, as described in DE 102010027619 B3. This also provides the advantage that the thermal energy provided by the antenna to the plasma source is substantially uniform along the length of the parallel antennas. This results in an apparatus capable of depositing thin layers to a substrate uniformly along the common axis of the plurality of antennas.

The linear plasma source assembly comprises one or more first gas conduit(s) (3) provided with first gas outlet ports (3a) for providing one or more first gaseous substances to a reactor. The one or more first gas conduits (3) allow for a first gas to be provided through the first gas outlet ports (3a) to the linear plasma source assembly. This allows for plasma forming gases to be provided to the linear plasma source and hence allow a plasma to be formed when the assembly is used.

The linear plasma source assembly may optionally comprise one or more second gas conduit(s) (4) provided with second gas outlet ports (4a) for providing one or more second gaseous substances to a reactor. The one or more second gas conduits (4) allow for a second gas to be provided through the second gas outlet ports (4a) to the linear plasma source assembly. This allows for gases to be provided to the linear plasma source that may reacts with gasses ionised at the linear plasma source.

The linear plasma source assembly comprises one or more exhaust gas conduit(s) (5) provided with exhaust gas inlet port(s) (5a) for removing one or more exhaust gaseous substances from a reactor. The linear plasma source assembly is provided with one or more exhaust gas conduits that allow waste gasses from the plasma deposition process to be removed from the linear plasma source assembly formed during use of the linear plasma source assembly through the exhaust gas inlet port(s). This advantageously allows for reduction of parasitic deposition in the linear plasma source during use of the linear plasma source.

Exhaust gas conduits in general have for instance been disclosed in U.S. Pat. Nos. 6,855,379 B2 and 6,044,792 A, however these are each not included into each manifold.

DE 102018113444B3 describes an alternative approach to parasitic deposition, by providing a separation wall that separates the space above and below the antenna, with only limited gas exchange between the two spaces, thereby separating the plasma generation from the plasma application. However, there is no disclosure of exhaust gas conduits.

The linear plasma source assembly preferably comprises a waveguide (11). The waveguide comprises a first input end portion (11c) and a first output end portion (11a) and second output end portion (11b). The waveguide is configured to propagate a radio wave from the input end portion (11c) such that the radio wave propagates from the first input end portion (11c) to the first output end portion (11a) and the second output end portion (11b). The first output end potion of the waveguide (11a) is configured to propagate a radio wave to the first end (2a) of the linear plasma source (7a) and the second output end portion of the waveguide (11b) is configured to propagate a radio wave to the second end of the linear plasma source (2b). This combination of features ensures propagation of the radio wave energy from a radio wave source through the waveguide and to the antenna of the linear plasma source. This provides the advantage that the thermal energy provided by the antenna to the plasma source is substantially uniform along the length of the antenna. This results in an apparatus capable of depositing thin layers to a substrate uniformly along the axis of the antenna.

The waveguide (11) preferably has a hollow structure or coaxial layout, which allows the radio wave to propagate in the internal space of the waveguide. Preferably, the waveguide (11) has a rectangular or circular cross-section orthogonal to the direction of radio wave propagation. More preferably, the waveguide (7) has a circular cross-section. The waveguide (11) can be made of metal such as copper, aluminium, iron or stainless steel or an alloy of those metals.

In an alternative, but equally preferable, embodiment to one in which linear plasma source assembly comprises a waveguide (11), the linear plasma source assembly comprises two radio wave source per linear plasma source (7a). In this embodiment, a first radio wave source (10A, 100) is configured to propagate a radio wave to the first end (2a) of the linear plasma source (7a) and the second radio wave source (10B, 100) is configured to propagate a radio wave to the second end of the linear plasma source (2b). This combination of features ensures propagation of the radio wave energy from a radio wave source through the waveguide and to the antenna of the linear plasma source. This provides the advantage that the thermal energy provided by the antenna to the plasma source is substantially uniform along the length of the antenna. This results in an apparatus capable of depositing thin layers to a substrate uniformly along the axis of the antenna.

Preferably, the linear plasma source assembly is one in which each gas manifold (9) additionally comprises: at least one second gas conduit(s) (4) provided with at least two gas outlet ports (4a) or at least two second gas conduits (4) provided with at least one gas outlet port (4a) for providing one or more second gaseous substances to a chemical vapour deposition chamber.

Preferably, the linear plasma source assembly additionally comprises a plurality of plasma confinement magnets (6). This advantageously provides a linear plasma assembly that allows for control of generated plasma fields and hence reduce parasitic deposition, and consequently minimizes line downtime and maximises line efficiency.

Preferably, each gas manifold (9) additionally comprises at least one second gas conduit(s) (4) provided with at least two gas outlet ports (4a) or at least two second gas conduits (4) provided with at least one gas outlet port (4a) for providing one or more second gaseous substances to a chemical vapour deposition chamber.

Preferably, the assembly additionally comprises a plurality of plasma confinement magnets (6).

Preferably, the first gas outlet ports of each gas manifold (9) are arranged in one or more set(s), with each set of first gas outlet port being configured in a linear array.

Preferably, the second gas outlet ports of each gas manifold (9) are arranged in one or more set(s), with each set of second gas outlet ports being configured in a linear array.

Preferably, the assembly comprises a plurality of exhaust gas inlet ports, wherein the exhaust gas inlet ports are arranged in one or more set(s), with each set of exhaust gas inlet ports being configured in a linear array.

Preferably, the assembly comprises:
i) two sets of first gas outlet ports arranged in linear arrays of first gas outlet ports;
ii) four sets of second gas outlet ports, where present, arranged in linear arrays of second gas outlet ports; and
iii) four sets of exhaust gas inlet ports arranged in linear arrays of exhaust gas inlet ports.

Preferably, the assembly comprises:
i) two sets of first gas outlet ports arranged in two linear arrays of first gas outlet ports, wherein the linear arrays of first gas outlet ports are located on opposite sides of the linear plasma source (2);
ii) four sets of second gas outlet ports, where present, are arranged in four linear arrays of second gas outlet ports, wherein pairs of linear arrays of second gas outlet ports are located on opposite sides of each gas manifold (9); and
iii) four sets of exhaust gas inlet ports arranged in four linear arrays of exhaust gas inlet ports, wherein pairs of linear arrays of exhaust gas inlet ports are located on opposite sides each gas manifold (9).

Preferably, the assembly possesses mirror symmetry. More preferably, the linear plasma source assembly possesses two-fold rotational symmetry with respect to the rotational axis of the linear plasma source (2).

Preferably, the first gas outlet ports (3a) are arranged evenly distributed along the gas manifolds (9) in rows, where the rows are parallel to the principle rotational axis of the antenna. Such an arrangement provides even better gas flow characteristics around the linear plasma source, further reducing parasitic deposition.

The first gas outlet ports (3a) may be of any suitable shape. Preferably, the first gas outlet ports (3a) are circular with a diameter of from 0.2 to 1.0 mm, more preferably 0.4 to 0.9 mm and most preferably of from 0.6 to 0.8 mm. These shapes and sizes were unexpectedly found to allow a more even gas flow within the linear plasma source assembly (1), further lowering parasitic deposition.

The first gas outlet ports (3a) are preferably arranged so that the shortest distance to the co-axial shielding element (8) is of from 20 mm to 80 mm, more preferably of from 30 mm to 70 mm, most preferably of from 40 to 60 mm. Such distances are believed to allow yet more optimal gas flow, which further minimizes parasitic deposition whilst providing sufficient first gas to the linear plasma source (2).

Preferably the first gas outlet ports (3a) are arranged such that the distance of the first gas outlet ports (3a) to the axis of the linear plasma source (2) are in the range of from 40 to 100 mm, more preferably from 50 to 90 mm and most preferably of from 60 to 80 mm.

Preferably the co-axial shielding element (8) has a diameter of from 10 mm to 80 mm, more preferably of from 20 mm to 60 mm, most preferably of from 30 to 40 mm.

Preferably, the exhaust gas inlet ports (5a) are slits over the full width of the source. More preferably, the exhaust gas inlet ports (5a) are slits have a width of from 1 to 20 mm, more preferably of from 4 to 12 mm, even more preferably of from 6 to 10 mm. Preferred slit shapes are selected from straight, trapezoid or 2 trapezoid shape. Preferably, the exhaust gas inlet ports (5a) extend for a length of 0.8 to 1.5 times the length of the linear plasma source (2), more preferably 0.9 to 1.3 times the length of the plasma source, most preferably 1.0 to 1.2 times the length of the plasma source. Without being bound by theory, it is believed that this length ratio relative to the length of the linear plasma source (2) advantageously allows for laminar gas flows during use of the apparatus, allowing for superior deposition to be realised. A particularly preferred combination of dimension for the exhaust gas inlet ports (5a) are those with a width of from 4 to 10 mm and a length of 1.0 to 1.2 times the length of the plasma source.

Preferably the exhaust gas inlet ports are arranged such that the distance of exhaust gas inlet ports to the axis of the linear plasma source (2) is from 80 to 200 mm, more preferably from 90 to 150 mm and most preferably of from 100 to 120 mm.

Preferably, the ratio of (i) the distance of exhaust gas inlet ports to the principle rotational axis of the linear plasma source (2) to (ii) the distance of the first gas outlet ports (3a) to the principle rotational axis of the linear plasma source (2) are in the range of from 1:1 to 5:1, more preferably of from 1.1:1 to 4:1, even more preferably of from 1.2:1 to 3:1 and most preferably of from 1.3:1 to 2:1.

The second gas outlet ports (4a) may be of any suitable shape. Preferably, the first gas outlet ports (4a) are circular with a diameter of from 0.2 to 1.0 mm, more preferably 0.4 to 0.9 mm and most preferably of from 0.6 to 0.8 mm. These shapes and sizes were unexpectedly found to allow a more even gas flow within the linear plasma source assembly (1), further lowering parasitic deposition.

The second gas outlet ports (4a) are preferably arranged so that the shortest distance to the co-axial shielding element (8) is of from 50 mm to 150 mm, more preferably of from 70 mm to 130 mm, even more preferably of from 80 mm to 110 mm, most preferably of from 90 to 100 mm. Such distances are believed to allow yet more optimal gas flow, which further minimizes parasitic deposition whilst providing sufficient second gas to the linear plasma source (2).

Preferably the second gas outlet ports (4a) are arranged such that the distance of the second gas outlet ports (4a) to the axis of the linear plasma source (2) are in the range of from 70 to 170 mm, more preferably from 90 to 150 mm and most preferably of from 110 to 120 mm.

Preferably, the ratio of (i) the distance of exhaust gas inlet ports to the principle rotational axis of the linear plasma source (2) to (iii) the distance of the second gas outlet ports (4a) to the principle rotational axis of the linear plasma source (2) are in the range of from 1:1 to 3:1, more preferably of from 1.05:1 to 2:1, even more preferably of from 1.15:1 to 1.75:1 and most preferably of from 1.2:1 to 1.5:1.

In a second aspect, the invention concerns an apparatus for plasma enhanced chemical vapour deposition of a coating onto a substrate, comprising:
a linear plasma source assembly (1) according to the invention;
a chemical vapour deposition chamber;
means for providing a substrate to the reaction chamber;
means for providing a first gas to the chemical vapour source assembly;
means for providing a second gas to the chemical vapour source assembly;
means for removing an exhaust gas from the chemical vapour source assembly.

Preferably, the apparatus additionally comprises rolling means configured to allow means configured to allow a substrate to be moved past the linear plasma source assembly according to any of the embodiments of the first aspect of the invention as disclosed above.

In a third aspect, the invention concerns a method for coating a substrate comprising the following steps:
i. provision of a substrate to a chemical vapour deposition chamber comprising a linear plasma source assembly (1) according to the invention;
ii. provision of energy to a linear plasma source;
iii. provision of a first gas and second gas to the chemical vapour source assembly;
iv. passing the substrate past a first side of the linear plasma source assembly to apply a first coating on a first surface of the substrate;
v. passing the first substrate past a second side of the linear plasma source assembly to apply a second coating on the substrate,
in which the first gas comprises a carrier gas and a reactant gas, the second gas comprises a precursor gas. Preferably the method according to the third aspect, is one where step (ii) comprises the provision of microwave energy to the linear plasma source.

The step (v) of the method may optionally: (a) deposit the second coating onto the first coating, or (b) deposit the second coating onto a second surface of the substrate.

Preferably, the substrate comprises copper, titanium, nickel, stainless steel or polymer film, preferably wherein the substrate is selected from a cladded foil or laminated foil comprising copper, titanium, nickel, stainless steel or polymer film.

Preferably, in the present method a material is deposited onto a substrate, where the material is selected from silicon, silicon nitride, silicon carbide or silica.

Preferably, in the present method coatings are deposited onto a conductive substrate, preferably for use in a Lithium battery. Preferably, in the present method anode materials are prepared by depositing silicon onto a conductive substrate. Preferably, in the present method silicon coatings are deposited onto a copper substrate.

Preferably, in the present method the first gas comprises a chemically inert carrier gas, preferably the inert carrier gas is selected from nitrogen helium, argon, or a combination of these gasses, most preferably the inert carrier gas is argon.

Preferably, in the present method the first gas comprises a reactive gas, preferably the reactive is selected from hydrogen, oxygen ammonia, nitrous oxide, methane, acetylene, ethane, ethene, propane, propene or any combination of these gasses, more preferably hydrogen.

Preferably, in the present method the first gas essentially consists of a chemically inert carrier gas and a reactive gas, preferably the chemically inert carrier gas is gas is selected from nitrogen helium, argon, or a combination of these gasses and the reactive gas is selected from hydrogen, oxygen ammonia, nitrous oxide, methane, acetylene, ethane, ethene, propane, propene or any combination of these gasses, more preferably the chemically inert carrier gas is argon and the reactive gas is hydrogen.

Preferably, in the present method the second gas comprises a precursor gas, more preferably the precursor gas is selected from SiH₄, SiH₃Cl, SiH₂Cl₂, SiHCl₃, SiCl₄, Si₂H₆, Si₂Cl₆, Si₃H₈, SiEt₂H₂ or cyclohexasilane.

Preferably, in the present method the second gas is a precursor gas, more preferably the precursor gas is selected from SiH₄, SiH₃Cl, SiH₂Cl₂, SiHCl₃, SiCl₄, Si₂H₆, Si₂Cl₆, Si₃H₈, SiEt₂H₂ cyclohexasilane.

Preferably, in the present method the first gas consists of a chemically inert carrier gas and a reactive gas and the second gas is a precursor gas, preferably the chemically inert carrier gas is argon, the reactive gas is hydrogen and the precursor gas is SiH₄.

### Description of the Embodiments

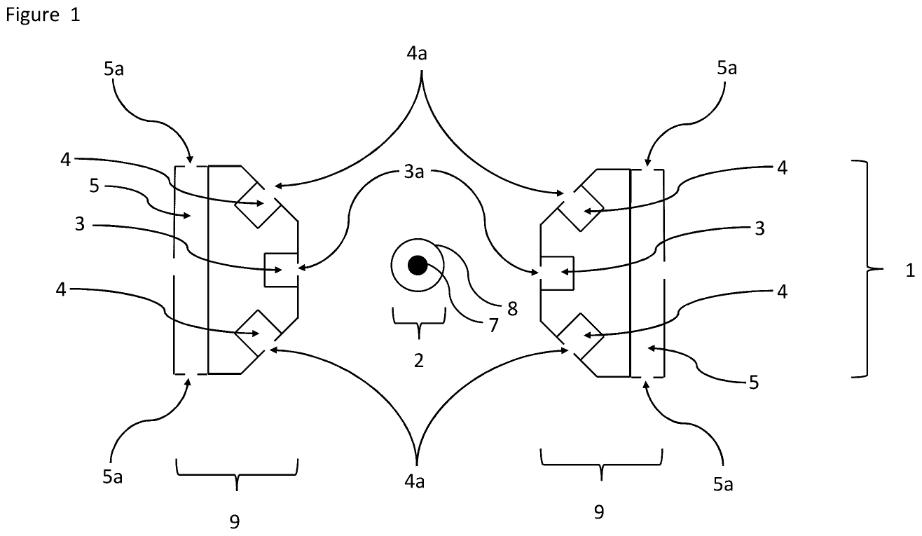

FIG. 1 depicts a cross-sectional view of a linear plasma source assembly according to an embodiment of a first aspect of the invention. The cross section is orthogonal to the principle rotational axis of the linear plasma source. In the embodiment depicted here, the linear plasma source assembly (1) comprises two gas manifolds (9) and a linear plasma source (2). The two gas manifolds (9) are arranged on opposite sides of the linear plasma source (2).

The linear plasma source (2) itself comprises an antenna (7) and a co-axial shielding element (8). The co-axial shielding element (8) is arranged around the antenna (7). By way of non-limiting example, the linear plasma source (2) may optionally comprise a copper metal antenna (107) and a quartz tube co-axial shielding element (108). Alternative metal antennas may be readily envisaged by the person having ordinary skill in the art, and by way of non-limiting example may be selected from an aluminium metal antenna (207) or a silver metal antenna (307). The co-axial shielding element (8) serves in part to protect the antenna (7) from the high temperatures of the plasma generated during PECVD. The antenna (7) possess a principle rotational axis which extends along the length of the antenna and about which the Coo rotational symmetry operator functions.

In the embodiment depicted in FIG. 1, each gas manifold (9) comprises one first gas conduit (3). In the depicted example, each first gas conduit comprises a plurality of first gas outlet ports (3a) and at least one first gas inlet (3b, not depicted). “Outlet” is used with respect to the gas conduit. These first gas outlet ports (3a) are depicted as circular, but their shape may optionally be altered. The first gas outlet ports (3a) are arranged on each gas manifold (9) in rows, where the rows are parallel to the principle rotational axis of the antenna (7). Such an arrangement has been identified as conferring better gas flow characteristics around the linear plasma source, further reducing parasitic deposition.

In operation, such as during PECVD, a first gas can be provided to the first gas conduit (3) of each gas manifold (9), which travels through the gas conduit (3) to the first gas outlet ports (3a). In operation, this allows the first gas to be provided from the first gas outlet ports (3a) to the linear plasma source (2), where the first gas is heated to form a plasma proximal to the linear plasma source (2).

In the embodiment depicted in FIG. 1, each gas manifold (9) comprises two second gas conduits (4). Each second gas conduit comprises a plurality of second gas outlet ports (4a) and at least one second gas inlet port (4b, not depicted). “Outlet” is used with respect to the gas conduit. By way of non-limiting example, these second gas outlets are arranged in rows, where each row is parallel to the principle rotational axis of the antenna (7).

In operation, such as during PECVD, a second gas can be provided to both the second gas conduits (4) of each gas manifold (9), which travels through the gas conduits (4) to the second gas outlet ports (4a). In operation, this allows the second gas to be provided from the gas conduits (4a) to the plasma generated by the linear plasma source (2).

In the embodiment depicted in FIG. 1, each gas manifold (9) comprises an exhaust gas conduit (5). Each exhaust gas conduit comprises a plurality of exhaust gas inlet ports (5a) and at least one exhaust gas outlet port (5b, not labelled in this depiction). “Inlet” is used with respect to the gas conduit. By way of non-limiting example, these exhaust gas inlet ports (5a) are arranged in slits, where each slit is parallel to the principle rotational axis of the antenna (7). The exhaust gas conduit (5) my optionally be attached to a vacuum generating means, such as an oil sealed rotary vane pump by way of non-limiting example. Such an optional vacuum generating means accelerates waste gas removal from the linear plasma source assembly (1), and thereby may advantageously allow further reduction in parasitic deposition.

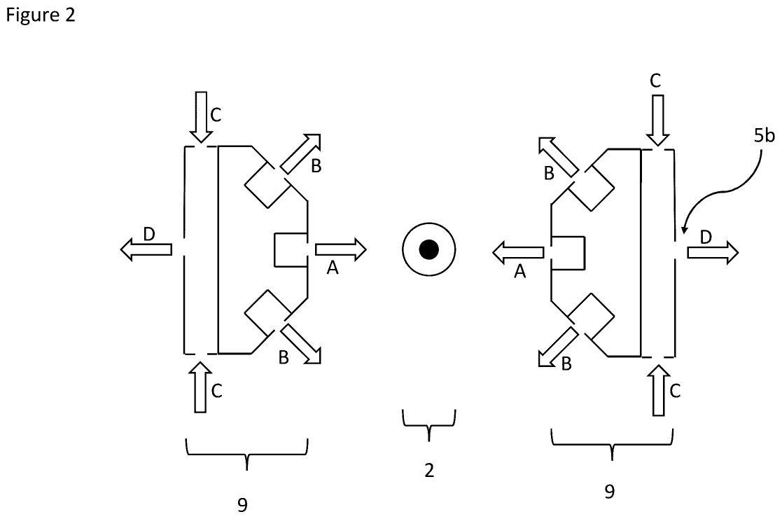

FIG. 2 is a cross-sectional view of the same linear plasma source assembly according to the embodiment of the first aspect of the invention, depicting the flow of gasses around the linear plasma source. The cross section is orthogonal to the principle rotational axis of the linear plasma source. The embodiment depicted is the same as that depicted in FIG. 1.

FIG. 2 depicts the flow of gasses that may be achieved by the linear plasma source assembly (1) of FIG. 1. Arrows (A) denote the flow of the first reactive gas from the first gas conduits (3, not labelled in this figure) through first gas outlets (3a, not labelled in this figure). Arrows (B) denote the flow of the second reactive gas from the second gas conduits (4, not labelled in this figure) through the second gas outlets (4a, not labelled in this figure). Arrows (C) denote the flow of exhaust gasses into the exhaust gas conduits (5, not labelled in this figure) via the exhaust gas inlets (5a, not labelled in this figure). Arrows (D) denote the flow of exhaust gasses out of the exhaust gas conduit (5, not labelled in this figure) through the exhaust gas outlet (5b), and consequently out of the linear plasma source assembly (1).

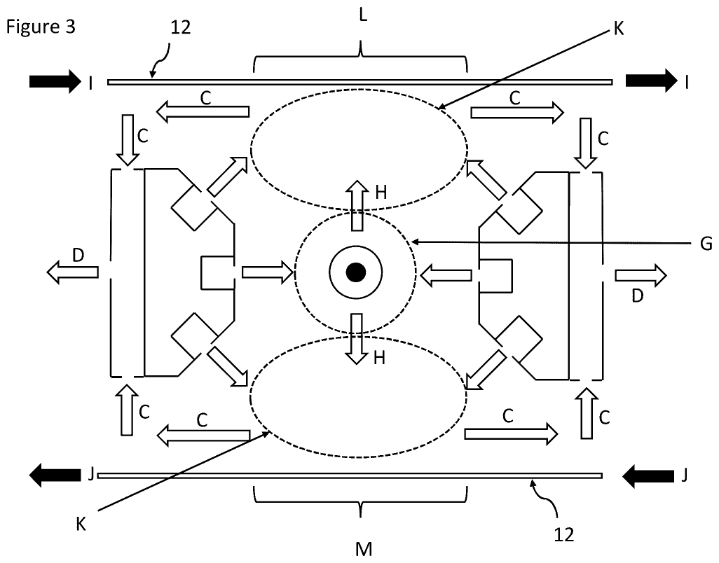

FIG. 3 is a cross-sectional view of the same linear plasma source assembly as depicted in FIGS. 1 and 2, depicting the assembly in use for depositing material onto a moving substrate according to a process according to the third aspect of the present invention. The method for coating a substrate depicted comprises the steps as described below.

The first step is the provision of a substrate (12) to a chemical vapour deposition chamber comprising a linear plasma source assembly as depicted in FIGS. 1 and 2. By way of non-limiting example, the substrate may be a film of copper foil, introduced to the linear plasma source assembly by means of rollers.

The second step is the provision of energy from an energy source, by way of non-limiting example a microwave generator (110), to the linear plasma source (2, not labelled in this figure).

The third step is the provision of a first gas, comprising a carrier gas and a reactant gas, and a second gas, comprising a precursor gas, to the chemical vapour source assembly. This is achieved as outlined above in the description of FIGS. 1 and 2. The provision of the first gas from the first gas conduits (3, not labelled in this figure), through the first gas outlet ports (3a, not labelled in this figure) to the linear plasma source (2, not labelled in this figure) allows the first gas to be provided to the linear plasma source (2, not labelled in this figure). The energy provided to the linear plasma source (2, not labelled in this figure) heats a fraction of first gas to form a plasma (G). The plasma ionises the remnants of the first gas which flows to the sides of the linear plasma source (2), depicted by arrow (H). In the deposition zones (K), the ionised first gas mixes with the second precursor gas. While the plasma propagates towards the substrates, its relative composition changes. The precursor gas reacts with the ionised first gas to form the deposition material. The deposition material is entrained in the flow of gasses.

The fourth step is passing the substrate past a first side of the linear plasma source assembly, depicted with arrow (I), to apply a first coating on a first surface of the substrate. This occurs by the flow of gasses from the deposition zone K bringing the entrained deposition material into contact with the substrate, forming a first coating on a first surface of the substrate. This occurs in the deposition region (L).

The fifth step is passing the first substrate past a second side of the linear plasma source assembly to apply a second coating on the substrate, depicted with arrow (J). This occurs in the same fashion as in the fourth step. This occurs in the deposition region (M).

The figure does not depict how the substrate it brought to pass past the second side of the linear plasma source assembly (1). However, the person possessing ordinary skill in the art can readily envisage such means. By way of a non-limiting example, a roller may be suitably employed.

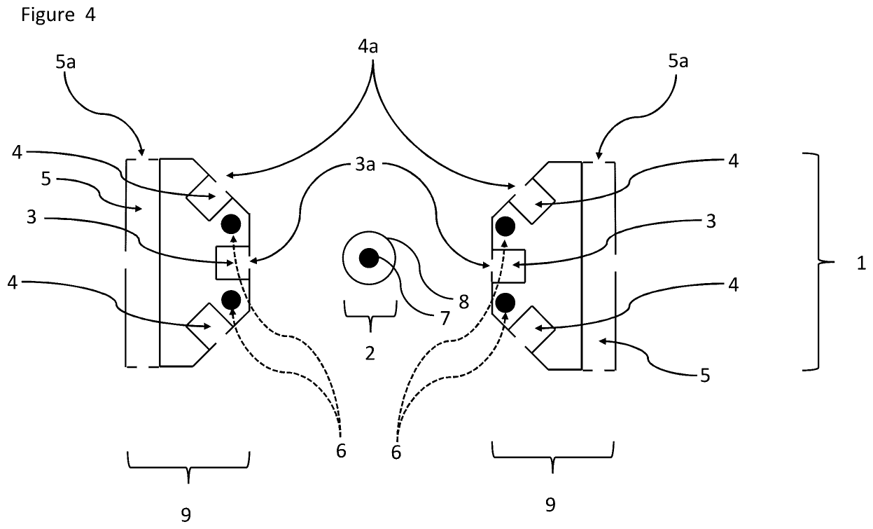

FIG. 4 depicts a cross-sectional view of a linear plasma source assembly according to an embodiment of the first aspect of the invention, which additionally comprises a plurality of plasma confinement magnets (6). The cross section is orthogonal to the principle rotational axis of the linear plasma source. The plasma confinement magnets (6) allow for control of plasma generated during PECVD. The plasma confinement magnets (6) are depicted as being located within the gas manifolds (9), but may also suitably be located on the exterior of the gas manifolds (9).

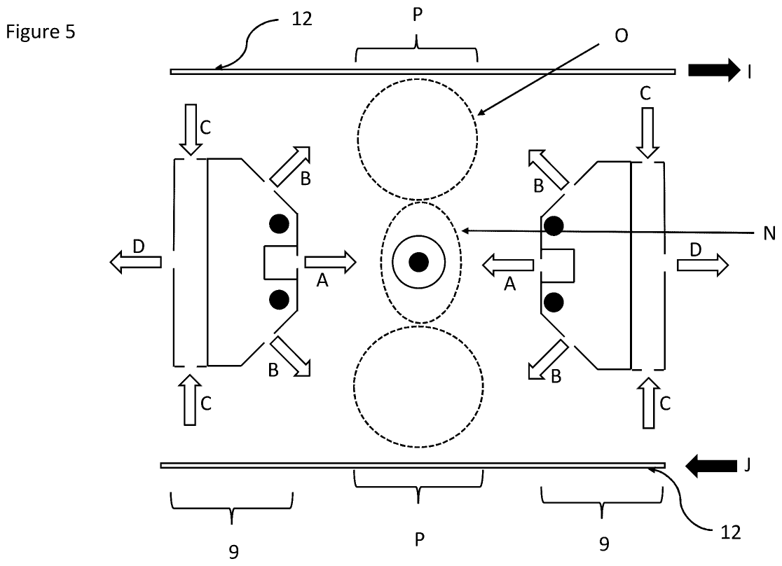

FIG. 5 is a cross-sectional view of the same linear plasma source assembly as depicted in FIG. 4, comprising plasma constraining magnets (6), used in a method according to the third aspect of the invention. It depicts the flow of gasses around the linear plasma source and the magnet constrained plasma (N). The cross section is orthogonal to the principle rotational axis of the linear plasma source. The plasma flow is shaped by the plasma confinement magnets (6). The magnets are configured to divert the plasma from the gas manifolds (9) and push it towards the substrate (12).

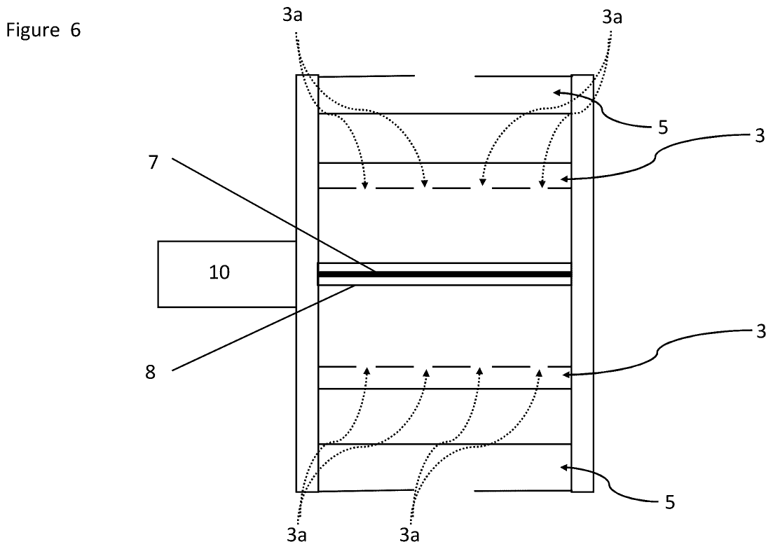

FIG. 6 is a cross-sectional view of the same linear plasma source assembly according to the embodiment of the first aspect of the invention as depicted in FIGS. 1-3. The cross section is parallel to, and cuts through, the principle rotational axis of the linear plasma source.

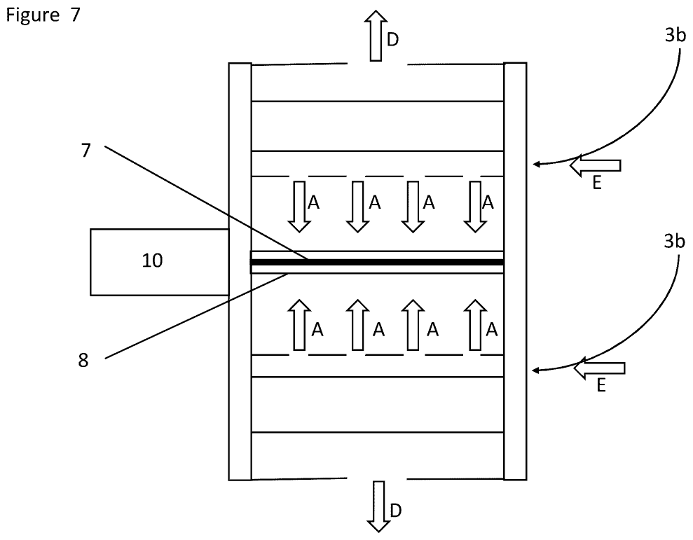

FIG. 7 is a cross-sectional view of the same linear plasma source assembly according to the embodiment of the first aspect of the invention, as depicted in FIGS. 1-3 and 6. The cross section is parallel to, and cuts through, the principle rotational axis of the linear plasma source. The flow of the first gas comprising a carrier gas and a reactant gas is depicted. The first gas is introduced to the first gas conduits (3, not depicted in this figure), and hence the linear plasma source assembly (1) via first gas inlets (3b). This flow of first gas into the first gas conduit (3) via first gas inlet (3b) is depicted by arrow (E). The first gas is conveyed to the first gas outlets (3a, not depicted in this figure) by the first gas conduits (3, not depicted in this figure). The first gas is provided to the linear plasma source (2) via first gas outlets (3a, not depicted in this figure), which results in the flow of first gas depicted by the arrows (A).

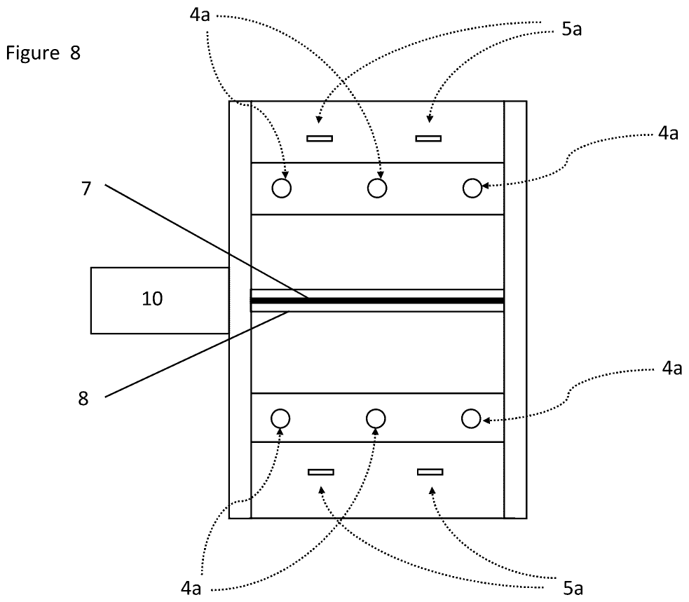

FIG. 8 is a top-down (birds-eye) view of the linear plasma source assembly according to the embodiment of the first aspect of the invention as depicted in FIGS. 1-3, 5 and 6.

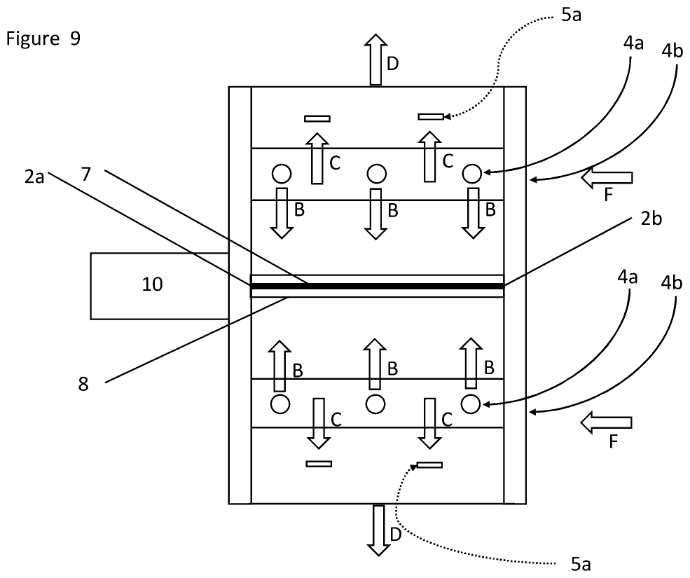

FIG. 9 is a top-down (birds-eye) view of the same linear plasma source assembly according to the embodiment of the first aspect of the invention as depicted in FIGS. 1-3 and 5-7, in use in a method according to the third aspect of the present invention. The arrows depict the flow of the second gas or gasses and the exhaust gas or gasses.

The flow of the second gas comprising precursor gas is depicted. The second gas is introduced to the second gas conduits (4, not depicted in this figure), and hence the linear plasma source assembly (1) via first gas inlets (4b). This flow of second gas into the second gas conduit (4) via second gas inlet(s) (4b) is depicted by arrow (F). The second gas is conveyed to the second gas outlets (4a) by the second gas conduits (4, not depicted in this figure). The second gas is provided to the deposition zones (K) via second gas outlets (4a), which results in the flow of second gas depicted by the arrows (B).

The flow of the exhaust gas is also depicted. The exhaust gas is removed from the exhaust gas conduits (5, not depicted in this figure), and hence the linear plasma source assembly (1) via exhaust gas outlets (4b, not depicted in this figure). This flow of exhaust gas from the exhaust gas conduit (5) via exhaust gas outlets (4b) is depicted by arrow (D). The exhaust gas is moved from the deposition zones (K) to the exhaust gas conduits (5) via the exhaust gas inlets (5a). The flow of exhaust gas into the exhaust gas conduits (5) via the exhaust gas inlets (5a) is depicted by arrows (C).

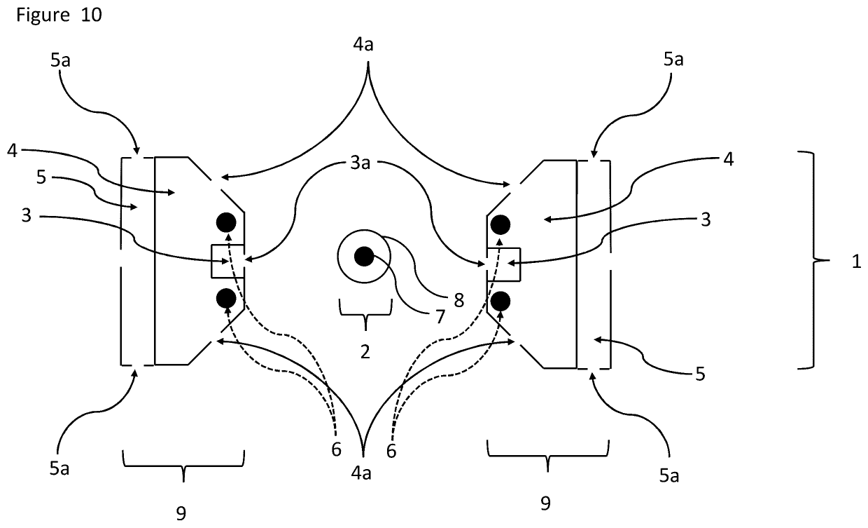

FIG. 10 is a cross-sectional view of a linear plasma source assembly according to an embodiment of a first aspect of the invention, comprising plasma constraining magnets (6). The cross section is orthogonal to the principle rotational axis of the linear plasma source.

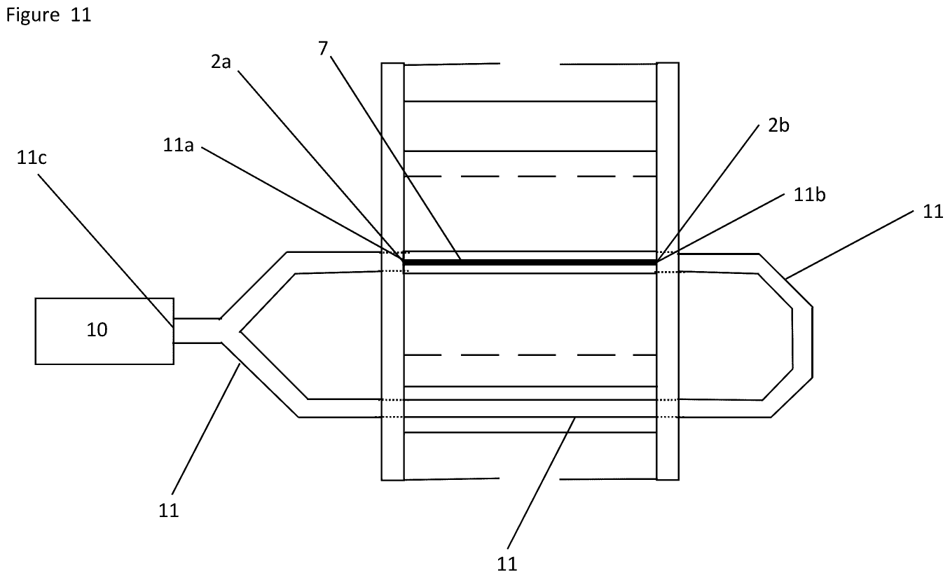

FIG. 11 is a cross-sectional view of a linear plasma source assembly according to an embodiment of the first aspect of the invention, comprising a waveguide (11). The cross section is parallel to, and cuts through, the principle rotational axis of the linear plasma source. The waveguide (11) is configured to receive radiation energy from the radiation source (10) into a first input end portion (11c). The waveguide is so configured as to pass this radiation energy to both a first output end portion (11a) and a second output end portion (11b). The first output end portion (11a) is configured to provide the radiation energy to the first end portion of linear plasma source (2a). The second output end portion (11b) is configured to provide the radiation energy to the second end portion of linear plasma source (2b). Surprisingly, it has been found that apparatus with this configuration is able to provide surprisingly stable plasma generation along lengths of antenna that cannot be achieved by provision of radiation energy to only one end of the antenna. This confers the unexpected advantage that such an apparatus may uniformly coat both sides of a substrate of greater width.

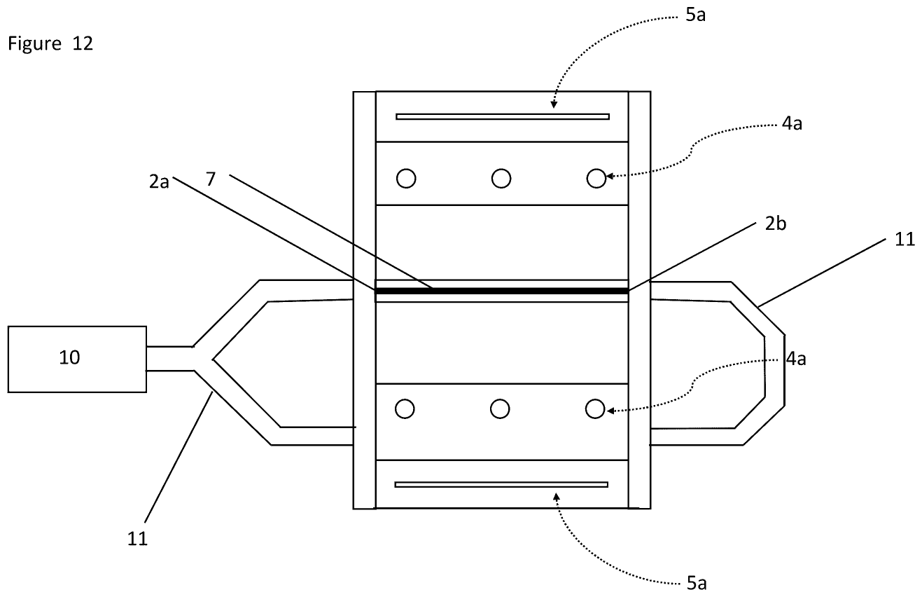

FIG. 12 is a top-down (birds-eye) view of a linear plasma source assembly according to an embodiment of the first aspect of the invention, comprising a waveguide (11).

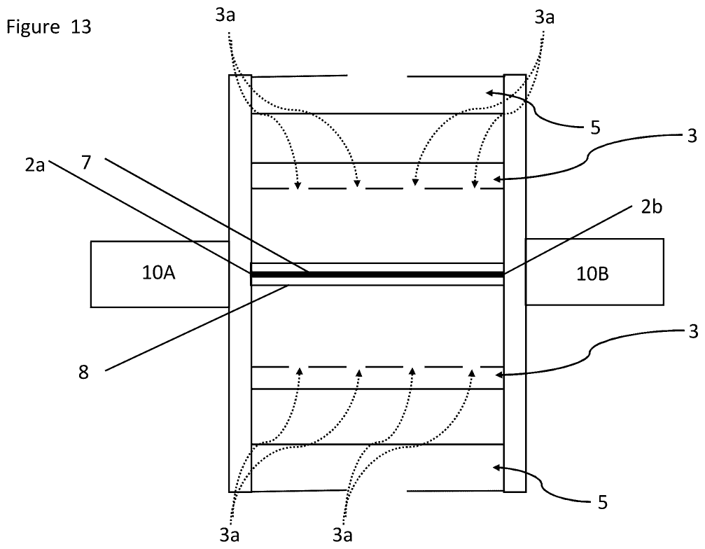

FIG. 13 is a cross-sectional view of a linear plasma source assembly according to an embodiment of the first aspect of the invention, in which the linear plasma source assembly comprises two radio wave source per linear plasma source (7a). In this embodiment, a first radio wave source (10A, 100) is configured to propagate a radio wave to the first end (2a) of the linear plasma source (7a) and the second radio wave source (10B, 100) is configured to propagate a radio wave to the second end of the linear plasma source (2b). This combination of features ensures propagation of the radio wave energy from a radio wave source through the waveguide and to the antenna of the linear plasma source. This provides the advantage that the thermal energy provided by the antenna to the plasma source is substantially uniform along the length of the antenna. This results in an apparatus capable of depositing thin layers to a substrate uniformly along the axis of the antenna. The first gas outlet ports (3a), second gas outlet ports (4a) and exhaust gas inlets (5a) are configured as for the embodiment depicted in FIGS. 6-9.

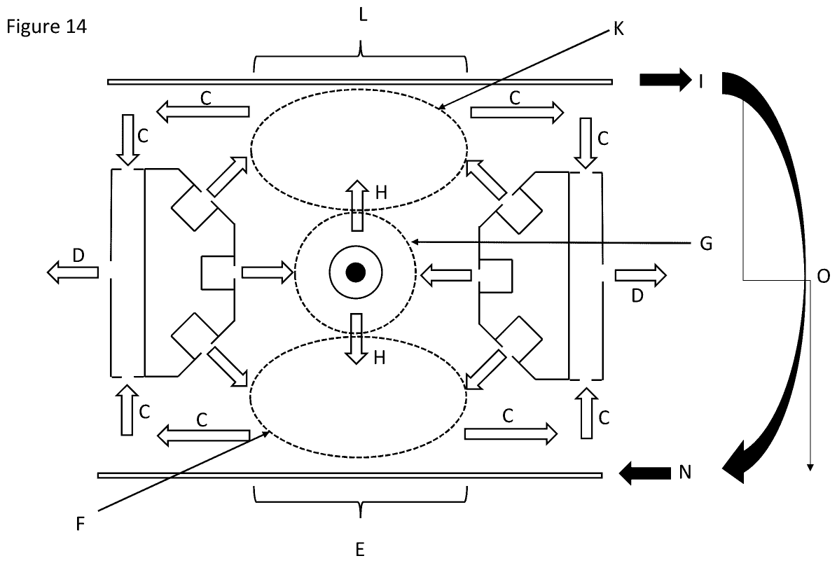

FIG. 14 is a cross-sectional view of the same linear plasma source assembly as depicted in FIGS. 1-3 and 6-9, used in a method according to the third aspect of the invention. It depicts the flow of gasses around the linear plasma source. The cross section is orthogonal to the principle rotational axis of the linear plasma source. The method for coating a substrate depicted comprises the steps as described below.

The first step is the provision of a substrate (12) to a chemical vapour deposition chamber comprising a linear plasma source assembly as depicted in FIGS. 1 and 2. By way of non-limiting example, the substrate may be a film of copper foil, introduced to the linear plasma source assembly by means of rollers.

The second step is the provision of energy to the linear plasma source, here from one energy source (10), by way of non-limiting example a microwave generator (110). It may be readily envisaged that a plurality of microwave generators (110A, 110B) may be used to provide microwave energy to the linear plasma source (2), such as with an apparatus according to the embodiment depicted in FIG. 13.

The third step is the provision of a first gas, comprising a carrier gas and a reactant gas, and a second gas, comprising a precursor gas, to the chemical vapour source assembly. This is achieved as outlined above in the description of FIGS. 1 and 2. The provision of the first gas from the first gas conduits (3, not labelled in this figure), through the first gas outlet ports (3a, not labelled in this figure) to the linear plasma source (2, not labelled in this figure) allows the first gas to be provided to the linear plasma source (2, not labelled in this figure). The energy provided to the linear plasma source (2, not labelled in this figure) heats a fraction of first gas to form a plasma (G). The plasma ionises the remnants of the first gas which flows to the sides of the linear plasma source (2), depicted by arrow (H). In the deposition zones (K), the ionised first gas mixes with the second precursor gas. While the plasma propagates towards the substrates, its relative composition changes. The precursor gas reacts with the ionised first gas to form the deposition material. The deposition material is entrained in the flow of gasses.

The fourth step is passing the substrate past a first side of the linear plasma source assembly, depicted with arrow (I), to apply a first coating on a first surface of the substrate. This occurs by the flow of gasses from the deposition zone K bringing the entrained deposition material into contact with the substrate, forming a first coating on a first surface of the substrate. This occurs in the deposition region (L).

The fifth step is passing the first substrate past a second side of the linear plasma source assembly to apply a second coating on the substrate, depicted with arrow (J). This occurs in the same fashion as in the fourth step. This occurs in the deposition region (M).

In this particular depiction, the fifth step is one in which the second coating is deposited onto the first coating. To achieve this the substrate (12) is passed past the first side of the linear plasma source assembly, depicted with arrow (I), to apply a first coating on a first surface of the substrate, then passed through a series of rollers (depicted with arrow “O”) to bring the coated first side of the substrate past the second side of the linear plasma source assembly. This ensures that coated first side of the substrate is brought proximal to the linear plasma source (2) and the second coating is deposited onto the first coating.

It can be readily envisaged that if between the first deposition zone L and the second deposition zone M, the substrate is passed through an inversion means (i.e. flipped through 180°), the method would be one in which step (v) of the method is one in which second coating is deposited onto a second surface of the substrate. This method advantageously provides a substrate in which two sides of the substate may be coated with an identical coating.

### LIST OF REFERENCE NUMERALS

Similar reference numbers used in the description to indicate similar elements (but only differences in hundreds) are implicitly included.
1 linear plasma source assembly.
2 linear plasma source.
2a first end portion of linear plasma source (2).
2b second end portion of linear plasma source (2).
3 first gas conduit(s).
3a first gas outlet port(s) (3a).
4 second gas conduit(s).
4a second gas outlet port(s).
5 exhaust gas conduit(s).
5a exhaust gas inlet port(s).
6 plasma confinement magnet(s).
7 antenna.
7a first end of antenna.
7b second end of antenna.
8 co-axial shielding element.
9 gas manifold.
10 radio wave source.
10A first radio wave source.
10B second radio wave source.
110 microwave radiation source.
11 waveguide.
11a first output end portion.
11b second output end portion.
11c first input end portion.
12 first substrate.
13 second substrate.
A flow of the first reactive gas from the first gas conduits (3) through first gas outlets (3a).
B flow of the second reactive gas from the second gas conduits (4) through the second gas outlets (4a).
C flow of exhaust gasses into the exhaust gas conduits (5) via the exhaust gas inlets (5a).
D flow of exhaust gasses out of the exhaust gas conduit (5) through the exhaust gas outlet (5b), and consequently out of the linear plasma source assembly (1).
E flow of first gas into the first gas conduit (3) via first gas inlet (3b).
F flow of second gas into the second gas conduit (4) via second gas inlet(s) (4b) is depicted by arrow (F).
G
H flow of ionised first gas which flows to the sides of the linear plasma source (2)
I direction of the substrate passing past a first side of the linear plasma source assembly.
J direction of the substrate passing past a second side of the linear plasma source assembly.
K deposition zone(s).
L First deposition region.
M Second deposition region.
N magnet constrained plasma
O moving the substrate by means of rollers.

1. A linear plasma source assembly for plasma enhanced chemical vapour deposition comprising:
a linear plasma source with first end and a second end comprising an antenna and a co-axial shielding element; and
at least two gas manifolds, each comprising
at least one first gas conduit(s) provided with at least one first gas outlet port for providing one or more first gaseous substances to a chemical vapour deposition chamber;
at least one exhaust gas conduit(s) each provided with at least two exhaust gas inlet port(s) for removing one or more exhaust gaseous substances from a chemical vapour deposition chamber.

2. The assembly according to claim 1, where each gas manifold additionally comprises at least one second gas conduit(s) provided with at least two gas outlet ports or at least two second gas conduits provided with at least one gas outlet port for providing one or more second gaseous substances to a chemical vapour deposition chamber.

3. The linear plasma source assembly according to claim 1, where the assembly additionally comprises a plurality of plasma confinement magnets.

4. The assembly according to claim 1, wherein the assembly possesses mirror symmetry.

5. The assembly according to claim 1, wherein the assembly possesses two-fold rotational symmetry with respect to the rotational axis of the linear plasma source.

6. An apparatus for plasma enhanced chemical vapour deposition of a coating onto a substrate, comprising:
a linear plasma source assembly according to claim 1;
a chemical vapour deposition chamber;
means for providing a substrate to the reaction chamber;
means for providing a first gas to the chemical vapour source assembly;
means for providing a second gas to the chemical vapour source assembly; and
means for removing an exhaust gas from the chemical vapour source assembly.

7. The apparatus according to claim 6, wherein apparatus additionally comprises means configured to allow a substrate to be moved past the linear plasma source assembly.

8. A method for coating a substrate comprising the following steps:
provision of a substrate to a chemical vapour deposition chamber comprising a linear plasma source assembly according to claim 1;
provision of energy to the linear plasma source;
provision of a first gas and second gas to the linear plasma source assembly;
passing a first substrate past a first side of the linear plasma source assembly to apply a first coating on a first surface of the substrate;
passing the first substrate past a second side of the linear plasma source assembly to apply a second coating on the substrate,
in which the first gas comprises a carrier gas and a reactant gas, the second gas comprises a precursor gas.

9. The method according to claim 8, wherein provision of energy to the linear plasma source further comprises the provision of microwave energy to the linear plasma source assembly.

10. The method according to claim 8, wherein the substrate comprises copper, titanium, nickel, stainless steel or polymer film.

11. The method according to claim 8, for depositing a material onto a substrate, wherein the material is selected from silicon, silicon nitride, silicon carbide or silica.

12. The method according to claim 8, for preparing anodes by depositing coatings onto a conductive substrate.

13. The method according to claim 8, for preparing anode materials by depositing silicon onto a conductive substrate.

14. The method according to claim 8, for preparing anode materials by depositing silicon onto a copper substrate.

15. The method according to claim 8, wherein the first gas comprises a chemically inert carrier gas.

16. The method according to claim 8, wherein the first gas comprises a reactive gas.

17. The method according to claim 8, wherein the first gas consists of a chemically inert carrier gas and a reactive gas.

18. The method according to claim 8, wherein the second gas comprises a precursor gas.

19. The method according to claim 8, wherein the second gas is a precursor gas.

20. The method according to claim 8, wherein the first gas consists of a chemically inert carrier gas and a reactive gas and the second gas is a precursor gas.
